(19) United States
(12) Patent Application Publication
(10) Pub. No.: US 2026/0136634 A1
(43) Pub. Date: May 14, 2026

(54) SEMICONDUCTOR DEVICES

(71) Applicant: Samsung Electronics Co., Ltd., Suwon-si (KR)

(72) Inventors: Sungnam Lyu, Suwon-si (KR); Sukhoon Kim, Suwon-si (KR); Hyojung Noh, Suwon-si (KR); Dosun Lee, Suwon-si (KR); Jaehun Han, Suwon-si (KR)

(21) Appl. No.: 19/332,380

(22) Filed: Sep. 18, 2025

(30) Foreign Application Priority Data
Nov. 13, 2024 (KR) 10-2024-0161057

(51) Int. Cl. H10D 64/66; H10B 12/00; H10D 30/00; H10D 62/10

(52) U.S. Cl. CPC H10D 64/669; H10B 12/30; H10D 30/503; H10D 62/121

(57) ABSTRACT

A semiconductor device includes channels extending in a first horizontal direction and spaced apart from each other in a second horizontal direction intersecting the first horizontal direction; a bit line extending in a vertical direction and contacting first ends of the channels; a gate electrode extending in the second horizontal direction and surrounding each of the channels; gate dielectric layers each arranged between the gate electrode and a respective channel of the channels; a mold surrounding the gate electrode; a metal growth suppression layer arranged between the gate electrode and the mold; and a data storage extending in the vertical direction and contacting second ends of the channels opposite the first ends of the channels.

### CROSS-REFERENCE TO RELATED APPLICATION(S)

This application claims the benefit under 35 USC 119(a) of Korean Patent Application No. 10-2024-0161057 filed on Nov. 13, 2024 in the Korean Intellectual Property Office, the entire disclosure of which is incorporated herein by reference for all purposes.

### BACKGROUND

Aspects of the present inventive concept relates to a semiconductor device, and more particularly, to a semiconductor device including three-dimensional channel structures.

As demand for high performance, high speed, and/or multifunctionality of semiconductor devices increases, the integration of semiconductor devices is increasing. In the case of conventional two-dimensional or planar semiconductor devices, the integration is mainly determined by the area covered by the unit memory cell array region, and is therefore affected by the level of fine pattern formation technology. Accordingly, three-dimensional semiconductor devices including memory cells arranged three-dimensionally are being proposed.

### SUMMARY

Example embodiments provide a semiconductor device having improved reliability.

According to example embodiments, a semiconductor device includes channels extending in a first horizontal direction and spaced apart from each other in a second horizontal direction intersecting the first horizontal direction; a bit line extending in a vertical direction and contacting first ends of the channels; a gate electrode extending in the second horizontal direction and surrounding each of the channels; gate dielectric layers each arranged between the gate electrode and a respective channel of the channels; a mold surrounding the gate electrode; a metal growth suppression layer arranged between the gate electrode and the mold; and a data storage extending in the vertical direction and contacting second ends of the channels opposite the first ends of the channels.

According to example embodiments, a semiconductor device includes channels arranged three-dimensionally in a vertical direction and a first horizontal direction; bit lines each extending in the vertical direction and contacting a first end of a respective channel of the channels; gate electrodes each surrounding a respective channel of the channels and extending in the first horizontal direction and spaced apart from each other in the vertical direction; gate dielectric layers each arranged between a respective channel of the channels and a corresponding gate electrode of the gate electrodes; metal growth suppression layers each arranged on an external surface of a respective gate electrode of the gate electrodes and spaced apart from each other in the vertical direction; and a data storage extending in the vertical direction and contacting second ends of the channels opposite to the first ends of the channels, wherein upper and lower surfaces of portions of the gate electrodes arranged between adjacent channels of the channels spaced apart in the first horizontal direction have, when viewed along the first horizontal direction, a concave profile in the vertical direction toward a center point between corresponding upper and lower surfaces, and wherein each of the metal growth suppression layers is arranged according to a surface profile of a corresponding gate electrode of the gate electrodes.

According to example embodiments, a semiconductor device includes a first region including a memory cell array; and a second region vertically overlapping the first region and including a peripheral circuit, wherein the memory cell array includes: channels extending in a first horizontal direction and spaced apart from each other in a second horizontal direction intersecting the first horizontal direction, each of the channels including a channel region and first and second source/drain regions separated by the channel region; bit lines each extending in a vertical direction intersecting the first horizontal direction and the second horizontal direction and contacting a first end of a respective channel of the channels; gate dielectric layers each surrounding a respective channel region of the channel regions of the channels; a gate electrode extending in the second horizontal direction and surrounding each of the gate dielectric layers; a metal growth suppression layer surrounding the gate electrode; and a data storage extending in the vertical direction and contacting second ends of the channels opposite to the first ends of the channels, wherein the gate electrode includes a conductive material, and wherein the metal growth suppression layer includes a polymer compound.

According to example embodiments, a method of manufacturing a semiconductor device includes alternately stacking sacrificial layers and preliminary semiconductor layers in a vertical direction; etching the alternately stacked sacrificial layers and preliminary semiconductor layers to form first openings extending in the vertical direction; removing the sacrificial layers to expose ends of the preliminary semiconductor layers; etching the preliminary semiconductor layers to form channels; forming gate dielectric layers each surrounding a respective channel of the channels; forming a capping layer surrounding the gate dielectric layers; forming a metal growth suppression layer surrounding the capping layer; removing the capping layer to form second openings between the metal growth suppression layer and the gate dielectric layers; and forming gate electrodes each filling a respective second opening of the second openings by depositing a metal base material such that the gate electrodes grow unidirectionally from the gate dielectric layers toward the metal growth suppression layer.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic perspective view of a semiconductor device according to an example embodiment.

FIG. 2 is a schematic perspective view of a memory cell of the semiconductor device of FIG. 1 according to an example embodiment.

FIG. 3 is a cross-sectional view illustrating an example embodiment of gate electrodes extending in one direction of the semiconductor device of FIG. 2.

FIGS. 4A and 4B are cross-sectional views illustrating embodiments of the semiconductor device along line I-I′ of FIG. 3.

FIGS. 5A, 5B, and 5C are cross-sectional views illustrating embodiments of the semiconductor device along line II-II′ of FIG. 3.

FIG. 6 is a cross-sectional view illustrating another embodiment of gate electrodes extending in one direction of the semiconductor device of FIG. 2.

FIG. 7 is a cross-sectional view illustrating another embodiment of the semiconductor device along line III-III′ of FIG. 6.

FIG. 8A is a partial enlarged cross-sectional view including a TEM image of a gate electrode of a gate structure of the semiconductor device of FIG. 3 according to an example embodiment.

FIG. 8B is a partial enlarged cross-sectional view including a TEM image of another embodiment of a gate electrode of a gate structure of a semiconductor device of FIG. 3.

FIGS. 9 to 18 are drawings illustrating a method of manufacturing a semiconductor device according to an example embodiment.

### DETAILED DESCRIPTION

Hereinafter, with reference to the attached drawings, an example embodiment will be described in more detail. The same reference numerals are used for the same components in the drawings, and duplicate descriptions of the same components are omitted.

An item, layer, or portion of an item or layer described as “extending” or as extending “lengthwise” in a particular direction has a length in the particular direction and a width perpendicular to that direction, where the length is greater than the width.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

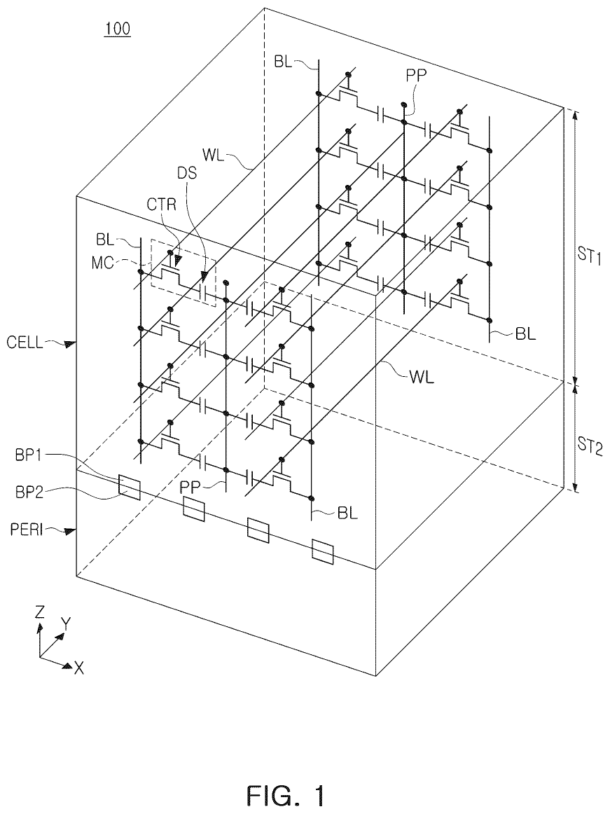

FIG. 1 is a schematic perspective view of a semiconductor device according to an example embodiment.

Referring to FIG. 1, the semiconductor device 100 may include a first structure ST1 (e.g., a first region) and a second structure ST2 (e.g., a second region) arranged below the first structure ST1. The first structure ST1 may be a first chip structure including a memory cell array region CELL (e.g., a memory cell array). The second structure ST2 may be a second chip structure including a peripheral circuit region PERI (e.g., a peripheral circuit). The first structure ST1 and the second structure ST2 may overlap in the vertical direction (Z-direction).

The memory cell array region CELL may include a memory cell array. In one example, the memory cell array may include memory cells MC arranged in a first direction (X-direction) and a second direction (Y-direction), word lines WL connected to the memory cells MC and extending in the second direction (Y-direction), and bit lines BL connected to the memory cells MC and extending in the third direction (e.g., the vertical direction or Z-direction).

The memory cells MC may have a structure in which two or more memory cells are stacked in a vertical direction (Z-direction). In one example, two memory cells MC may be arranged in a horizontal direction as a pair.

Each of the memory cells MC may include a cell transistor CTR and a data storage structure DS that may serve as data storage. The cell transistor CTR and the data storage structure DS may be arranged in a horizontal arrangement extending along the first direction (X-direction). For example, the data storage structure DS may be positioned next to the corresponding cell transistor CTR in the first direction (X-direction).

The gate of the cell transistor CTR may be connected to the word line WL, the first source/drain region of the cell transistor CTR may be connected to the bit line BL, and the second source/drain region of the cell transistor CTR may be connected to the data storage structure DS.

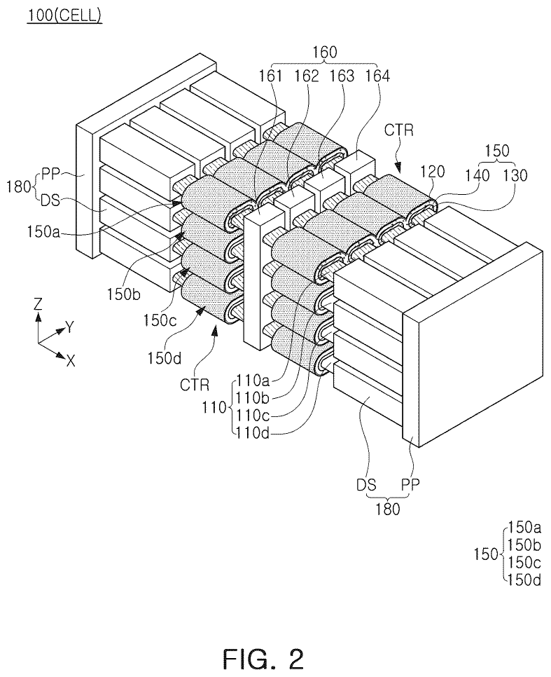

In a memory such as a DRAM, the data storage structure DS may be a cell capacitor capable of storing data. The data storage structures DS may share one or more plate electrodes PP. For example, the plate electrodes PP may extend in a vertical direction and be electrically connected to the data storage structures DS. In one example, the plate electrodes PP may be spaced apart from each other in a second direction (Y-direction) and may extend in a third direction (Z-direction). The plate electrode PP may be parallel to the bit line BL. The plate electrode PP may be vertically oriented. The plate electrode PP may be referred to as a vertical plate electrode. The memory cells MC arranged horizontally as a pair may share one plate electrode PP. For example, each plate electrode PP may have a plate shape oriented in a Y-Z plane as shown, e.g., in FIG. 2. For example, the plate electrodes PP may be spaced apart from each other in the first direction (X-direction) as shown, e.g., in FIG. 2.

The memory cells MC may be arranged between bit lines BL and plate electrodes PP. The memory cells MC may be arranged in a horizontal arrangement in a first direction (X-direction). Each of the memory cells MC may be connected to one bit line of the bit lines BL, one word line of the word lines WL, and one plate electrode of the plate electrodes PP.

The word lines WL may be spaced apart from each other in the first direction (X-direction) and may extend in the second direction (Y-direction). The word lines WL may be arranged vertically in the third direction (Z-direction). In one example, the word lines WL may be horizontally oriented with respect to a plane of the second structure ST2. The word lines WL may be referred to as horizontal word lines. A plurality of memory cells MC arranged horizontally along the second direction (Y-direction) may be connected to one word line WL.

The bit lines BL may be spaced apart from each other in the second direction (Y-direction) and may extend in the third direction (Z-direction). The bit lines BL may be vertically oriented from the plane of the second structure ST2. The bit lines BL may be referred to as vertical bit lines. A plurality of memory cells MC arranged vertically along the third direction (Z-direction) may be connected to one bit line BL.

The peripheral circuit area PERI may be electrically connected to the memory cell array area CELL. The peripheral circuit area PERI may include peripheral circuit elements. For example, it may include sub-word line drivers electrically connected to word lines WL, and sense amplifiers electrically connected to bit lines BL.

The first structure ST1 may be bonded to the second structure ST2. For example, the first structure ST1 may include first bonding pads BP1 on the lower surface thereof, and the second structure ST2 may include second bonding pads BP2 on the upper surface thereof. The first bonding pads BP1 may be bonded to the second bonding pads BP2, and may electrically connect the first structure ST1 to the second structure ST2. For example, the first bonding pads BP1 and the second bonding pads BP2 may provide a path for electrically connecting the memory cell array region CELL to the peripheral circuit region PERI.

In this document, the first direction (X-direction) and the second direction (Y-direction) may be referred to as horizontal directions, and the third direction (Z-direction) may be referred to as a vertical direction.

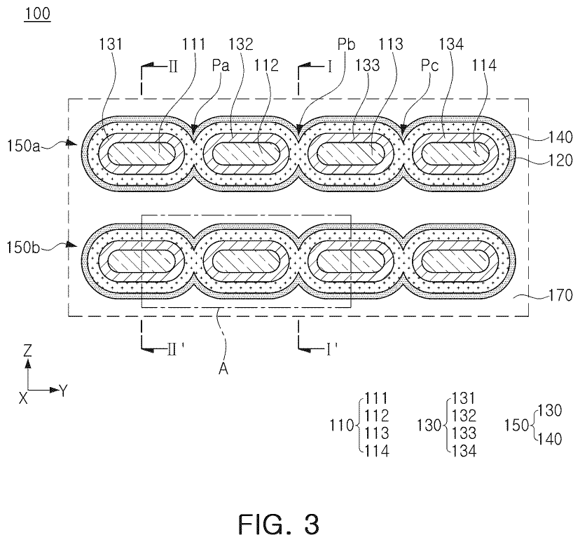

FIG. 2 is a schematic perspective view of a memory cell of the semiconductor device of FIG. 1 according to an example embodiment. FIG. 3 is a cross-sectional view illustrating an example embodiment of gate electrodes extending in one direction of the semiconductor device of FIG. 2.

Referring to FIGS. 2 and 3, the memory cell array region CELL of the semiconductor device 100 may include gate structures 150, vertical conductive electrodes 160, capacitor structures 180, cell transistors CTR disposed between the vertical conductive electrodes 160 and the capacitor structures 180, and metal growth suppression layers 120 surrounding the gate structures 150. The semiconductor device 100 may further include a mold structure 170 surrounding the gate structures 150.

The cell transistors CTR may include channel structures 110. Each of the channel structures 110 may include a channel region surrounded by a gate structure 150, a first source/drain region in contact with a respective or corresponding vertical conductive electrode 160, and a second source/drain region in contact with a respective or corresponding capacitor structure 180. The channel region may be disposed between the first source/drain region and the second source/drain region in the first direction (X-direction). The cell transistor CTR may include a gate all around field effect transistor (GAA FET).

The channel structures 110 may include a plurality of channel structures 110a, 110b, 110c, 110d extending in a first direction (X-direction) and spaced apart in a second direction (Y-direction) and a third direction (Z-direction). The above-described plurality of channel structures 110a, 110b, 110c, 110d may include a first channel structure 110a, a second channel structure 110b, a third channel structure 110c, and a fourth channel structure 110d extending in a first direction (X-direction) and spaced apart from each other in a vertical direction (Z-direction).

Each of the first channel structure 110a, the second channel structure 110b, the third channel structure 110c, and the fourth channel structure 110d may include a first channel layer 111, a second channel layer 112, a third channel layer 113, and a fourth channel layer 114 extending in a first direction (X-direction) and spaced apart from each other in a second direction (Y-direction). Each of the first channel structure 110a, the second channel structure 110b, the third channel structure 110c, and the fourth channel structure 110d is illustrated as including four channel layers, but is not limited thereto, and may include three or fewer channel layers or five or more channel layers.

The channel structures 110 may include a semiconductor material, for example, silicon, germanium, or silicon-germanium.

The vertical conductive electrodes 160 may include a plurality of vertical conductive electrodes (161 to 164) extending in the vertical direction (Z-direction) and spaced apart from each other in the second direction (Y-direction). The vertical conductive electrodes 160 may contact the first ends of respective channel structures of the channel structures 110. In one example, the plurality of vertical conductive electrodes (161 to 164) may include a first vertical conductive electrode 161, a second vertical conductive electrode 162, a third vertical conductive electrode 163, and a fourth vertical conductive electrode 164. In one example, the first vertical conductive electrode 161 may be in contact with first ends of the first channel layers 111 of the first to fourth channel structures (110a to 110d). The second vertical conductive electrode 162 may be in contact with first ends of the second channel layers 112 of the first to fourth channel structures (110a to 110d). The third vertical conductive electrode 163 may be in contact with first ends of the third channel layers 113 of the first to fourth channel structures (110a to 110d). The fourth vertical conductive electrode 164 may be in contact with the first ends of the fourth channel layers 114 of the first to fourth channel structures (110a to 110d).

The vertical conductive electrodes 160 may include doped polysilicon, a metal, a conductive metal nitride, a metal-semiconductor compound, a conductive metal oxide, conductive graphene, carbon nanotubes, or a combination thereof. For example, at least one of the vertical conductive electrodes 160 may be made of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotubes, or a combination thereof. Each of the vertical conductive electrodes 160 may correspond to a bit line BL of FIG. 1, and the vertical conductive electrodes 160 may collectively be referred to as a bit line structure.

The gate structures 150 may surround channel regions of the channel structures 110 arranged between the vertical conductive electrodes 160 and the capacitor structures 180. Each of the gate structures 150 may be arranged in a gate all around structure that surrounds the channel structures 110.

Each of the gate structures 150 may include a plurality of gate structures 150a, 150b, 150c, 150d that extend in the second direction (Y-direction) and are mutually spaced apart in the third direction (Z-direction).

Each of the gate structures 150 may include gate dielectric layers 130 surrounding channel structures 110 spaced apart in the second direction (Y-direction) and gate electrodes 140 surrounding channel structures 110 spaced apart in the second direction (Y-direction) on the gate dielectric layers 130. Each of the gate electrodes 140 may be arranged in a gate all around structure surrounding the channel structures 110. Each of the gate electrodes 140 may correspond to a word line WL of FIG. 1.

The gate structures 150 may include a plurality of gate structures 150a, 150b, 150c, 150d extending in the second direction (Y-direction) and spaced apart from each other in the third direction (Z-direction). The gate structures 150a, 150b, 150c, 150d may include a first gate structure 150a surrounding a first channel structure 110a, a second gate structure 150b surrounding a second channel structure 110b, a third gate structure 150c surrounding a third channel structure 110c, and a fourth gate structure 150d surrounding a fourth channel structure 110d. For example, each of the first to fourth gate structures (150a to 150d) may include first to fourth gate dielectric layers (131 to 134) surrounding the first to fourth channel layers (111 to 114) of the first to fourth channel structures (110a to 110d), respectively, and a gate electrode 140 disposed on (e.g., surrounding or covering) the first to fourth gate dielectric layers (131 to 134).

The gate dielectric layers 130 may include a first gate dielectric layer 131 surrounding the first channel layer 111, a second gate dielectric layer 132 surrounding the second channel layer 112, a third gate dielectric layer 133 surrounding the third channel layer 113, and a fourth gate dielectric layer 134 surrounding the fourth channel layer 114 in each of the first to fourth channel structures (110a to 110d). In one example, the first gate dielectric layer 131, the second gate dielectric layer 132, the third gate dielectric layer 133, and the fourth gate dielectric layer 134 may be spaced apart from each other in the second direction (Y-direction). In one example, the first to fourth gate dielectric layers (131 to 134) may be in contact with the inner surface of the gate electrode 140.

Each of the gate electrodes 140 may surround the first to fourth gate dielectric layers (131 to 134). The gate electrode 140 may extend in the second direction (Y-direction) and surround the first to fourth gate dielectric layers (131 to 134) that are spaced apart in the second direction (Y-direction). In one example, the portion of the gate electrode 140 that does not overlap the first to fourth gate dielectric layers (131 to 134) (and the channel structures 110) in the vertical direction (Z-direction) may include recessed regions Pa, Pb, Pc that are recessed toward the channel structures 110. For example, the gate electrode 140 that fills a space extending in the second direction (Y-direction) between the first gate dielectric layer 131 surrounding the first channel layer 111 and the second gate dielectric layer 132 surrounding the second channel layer 112 may include a first recessed region Pa that is recessed toward the first and second gate dielectric layers 131, 132. For example, the upper surface and the lower surface of the gate electrode 140 disposed between the first gate dielectric layer 131 and the second gate dielectric layer 132 in the second direction (Y-direction) may have a concave profile in the direction between the upper surface and the lower surface of the gate electrode 140. For example, when viewed along the first direction (X-direction) as shown, e.g., in FIG. 3, an upper portion of the gate electrode 140 may be recessed toward a lower portion of the gate electrode 140 in the vertical direction and the lower portion of the gate electrode 140 may be recessed toward the upper portion of the gate electrode 140 in the vertical direction. For example, upper and lower portions or surfaces of the gate electrode 140 may be pinched toward each other in regions between adjacent channel structures in the second direction (Y-direction).

The gate electrode 140 filling the space between the second gate dielectric layer 132 surrounding the second channel layer 112 and the third gate dielectric layer 133 surrounding the third channel layer 113 may include a second recessed region Pb that is concavely recessed toward the second and third gate dielectric layers 132, 133. For example, the upper surface and the lower surface of the gate electrode 140 disposed between the second gate dielectric layer 132 and the third gate dielectric layer 133 may have a concave profile in the direction between the upper surface and the lower surface of the gate electrode 140.

The gate electrode 140 filling between the third gate dielectric layer 133 surrounding the third channel layer 113 and the fourth gate dielectric layer 134 surrounding the fourth channel layer 114 may include a third recessed region Pc that is concavely recessed toward the third and fourth gate dielectric layers 133, 134. For example, the upper surface and the lower surface of the gate electrode 140 positioned between the third gate dielectric layer 133 and the fourth gate dielectric layer 134 may have a concave profile in the direction between the upper surface and the lower surface of the gate electrode 140.

The gate dielectric layers 130 may include at least one of silicon oxide, silicon nitride, a low-k material, and a high-κ material. The high-κ dielectric material may mean a dielectric material having a higher dielectric constant than silicon oxide, and the low-k dielectric material may mean a dielectric material having a lower dielectric constant than silicon oxide. The high-κ dielectric material may be, for example, a metal oxide or a metal oxynitride. The high-κ dielectric material may be, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La2O3), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). The gate dielectric layers 130 may be formed as a single layer or multiple layers of the materials described above.

The gate electrode 140 may include at least one of TiN, TiAlC, TiAlN, TiSiN, TiWN, Mo, MoSi, MoSiN, MoN, W, Ta, TaN, LaN, Al, Cu, and Ru.

Each of the metal growth suppression layers 120 may surround an external surface of each of the gate structures 150. In one example, the metal growth suppression layer 120 may be in contact with an external surface of the gate electrode 140. Each of the metal growth suppression layers 120 may be conformally arranged according to a surface profile of the gate electrode 140 of each of the gate structures 150. For example, since the gate electrode 140 includes first, second and third recessed regions Pa, Pb, Pc that are concavely recessed toward the channel structure 110, the metal growth suppression layer 120 may also have a surface profile that is concavely recessed toward the channel structure 110 correspondingly. In one example, the thickness of the metal growth suppression layer 120 in a direction perpendicular to an outer surface of the gate dielectric layer 130 may be smaller than the thickness of the gate electrode 140 in the direction perpendicular to the outer surface of the gate dielectric layer 130.

The metal growth suppression layers 120 may include a deposition inhibitor. The deposition inhibitor may chemically deactivate the metal. Accordingly, a metal material is not deposited on the surface of the metal growth suppression layers 120. In one example, the deposition inhibitor may include a polymer compound, for example, octadecylphosphonic acid (ODPA). However, the present inventive concept is not limited thereto, and the deposition inhibitor may include at least one of Octylphosphonic acid (OPA), Eicosapentaenoic acid (EPA), Polyphthalamide (PPA), N,N-dimethylaminotrimethylsilane (DMATMS), Tetra Methylammonium Hydroxide (TMH), Ceftazidime (CAZ), and Trimethoxy-(pentamethylcyclopentadienyl)-titanium(IV) (TMPMCT).

The mold structure 170 may cover the gate structures 150. For example, the mold structure 170 may be disposed on the external surface of the metal growth suppression layer 120 and may fill the space between the metal growth suppression layers 120 spaced apart in the vertical direction (Z-direction). In one example, the mold structure 170 may include a plurality of insulating layers. In one example, the mold structure 170 may include an insulating material. For example, the mold structure 170 may include at least one of SiO, SiN, SiCN, SiOC, SiON, and SiOCN. The mold structure 170 may be referred to as a cell insulation layer for the memory cell array region CELL of FIG. 1.

Each of the capacitor structures 180 may include data storage structures DS and plate electrodes PP connected to the data storage structures DS.

The data storage structures DS may be in contact with second ends opposite to the first ends of the channel structures 110 in the first direction (X-direction). Each of the data storage structures DS may be in contact with second ends of the first to fourth channel layers (111 to 114) constituting the first to fourth channel structures (110a to 110d), respectively. The data storage structures DS may be electrically connected to second source/drain regions of the channel structures 110.

The semiconductor device 100 according to embodiments includes three-dimensionally arranged channel structures 110, a gate electrode 140 surrounding channel regions CH of the channel structures 110 spaced apart in a second horizontal direction (Y-direction), and a metal growth suppression layer 120 surrounding an external surface of the gate electrode 140. During the manufacturing process of the semiconductor device 100, the gate electrode 140 may be formed on surfaces of the gate dielectric layers 130 surrounding each of the channel regions CH of the channel structures 110 only in a direction orthogonal to the surfaces of the gate dielectric layers 130, without forming voids inside. Accordingly, a semiconductor device with improved electrical characteristics may be provided.

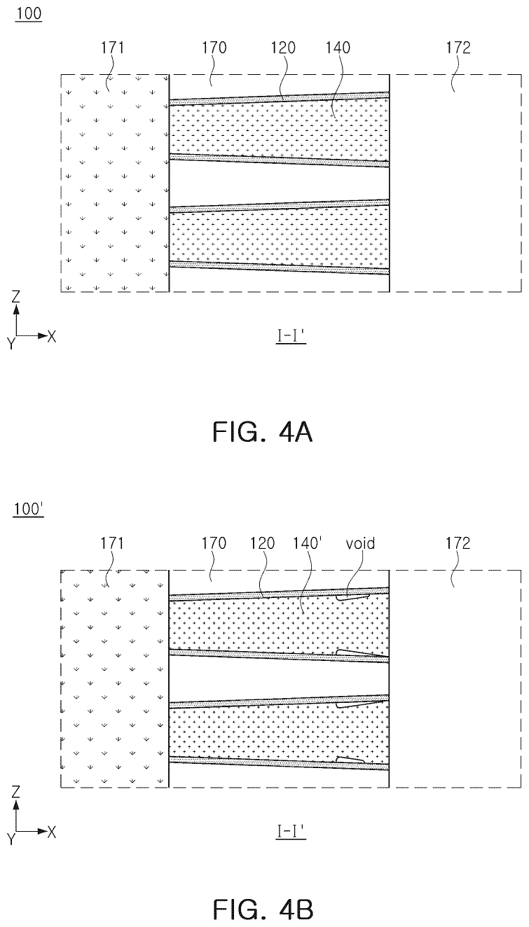

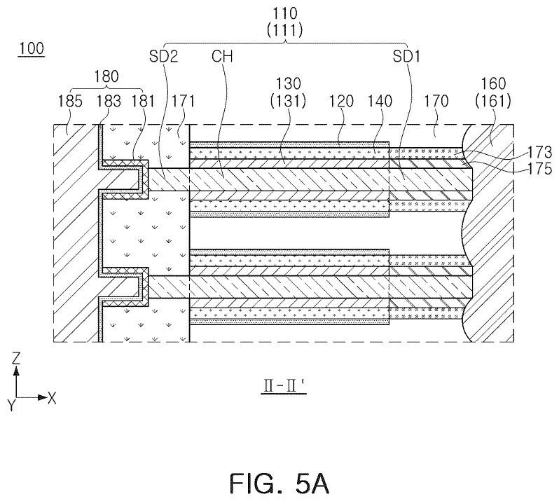

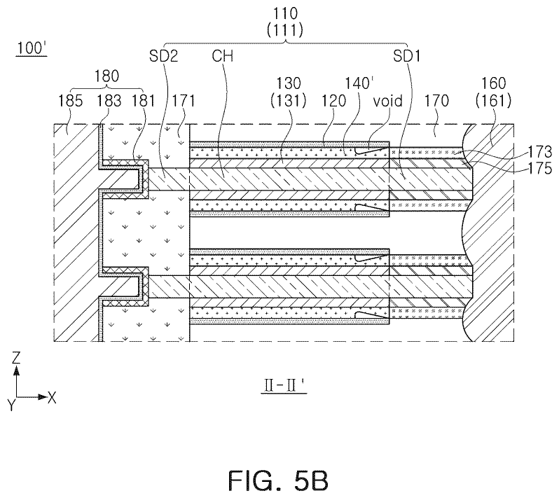

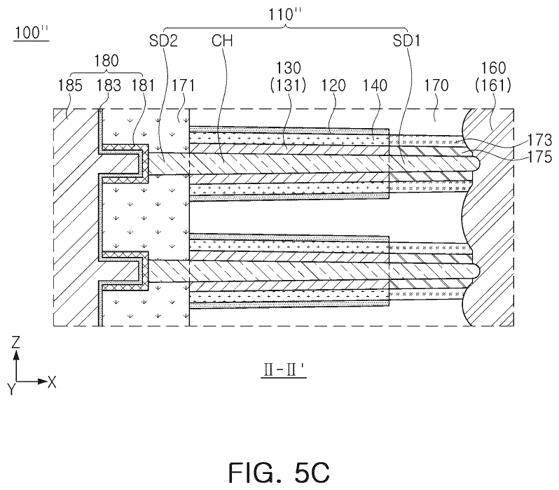

FIGS. 4A and 4B are vertical cross-sectional views illustrating embodiments of the semiconductor device illustrated in FIG. 3 along line I-I′. FIGS. 5A, 5B, and 5C are vertical cross-sectional views illustrating embodiments of the semiconductor device illustrated in FIG. 3 along the line II-II′.

Referring to FIGS. 3, 4A, and 5A, the semiconductor device 100 may further include a first insulating layer 171 that fills a space between the capacitor structure 180 and the gate structures 150 and contacts one ends (e.g., first ends) of the gate structures 150, and a second insulating layer 172 that is spaced apart from the first insulating layer 171 in the first direction (X-direction) and contacts the other ends (e.g., second ends) of the gate structures 150 opposite to the one ends. In one example, a mold structure 170 may be arranged between the first insulating layer 171 and the second insulating layer 172.

The first insulating layer 171 may be in contact with one side of the gate electrode 140 and one side of the metal growth suppression layer 120 surrounding the gate electrode 140 in the first direction (X-direction). In one example, the second insulating layer 172 may be in contact with the other side of the gate electrode 140 and the other side of the metal growth suppression layer 120 in the first direction (X-direction).

Referring to FIG. 4A together with FIG. 3, the closer to the first insulating layer 171, the smaller the height of the gate electrode 140 arranged between the channel structures 110 in the vertical direction (Z-direction). In one example, the closer to the first insulating layer 171, the smaller the cross-sectional area of the gate electrode 140. The cross-sectional area of the gate electrode 140 may mean the cross-sectional area in the second direction (Y-direction) or in the Y-Z plane when viewed along the first direction (X-direction). In another embodiment, unlike the illustration of FIG. 4A, the height of the gate electrode 140 disposed between the channel structures 110 in the vertical direction (Z-direction) may be constant closer to the first insulating layer 171.

Referring to FIG. 5A together with FIG. 3, the semiconductor device 100 may include a vertical conductive electrode 160 connected to the first source/drain regions SD1 of the channel structures 110, a capacitor structure 180 connected to the second source/drain regions SD2 of the channel structures 110, an insulating liner 175 surrounding the channel structures 110 exposed between the gate electrode 140 and the vertical conductive electrode 160, and a gate capping layer 173 surrounding the insulating liner 175.

The vertical conductive electrode 160 may extend in the vertical direction (Z-direction) and be electrically connected to the first source/drain regions SD1 of the channel structures 110 that are spaced apart in the vertical direction (Z-direction). For example, the first vertical conductive electrode 161 may be connected to the first source/drain regions SD1 of the first channel layers 111 of the channel structures 110.

The capacitor structure 180 may include first electrodes 181, a second electrode 185, and a capacitor dielectric layer 183 disposed between the first electrodes 181 and the second electrode 185.

The first electrodes 181 may have a cylindrical shape oriented in a horizontal direction (e.g., a flat end of the cylindrical shape may be oriented in a Y-Z plane). The first electrodes 181 may be electrically connected to the second source/drain regions SD2 of the channel structures 110. The capacitor dielectric layer 183 is disposed between the first electrodes 181 and the second electrode 185 and may extend in a vertical direction (Z-direction) from the inner wall of the first electrodes 181 to conformally cover the space between the first electrodes 181. The second electrode 185 may be in contact with the capacitor dielectric layer 183. The second electrode 185 may include a plurality of conductive layers. The second electrode 185 may be arranged in a form extending from the inner wall of the first electrodes 181 on the capacitor dielectric layer 183 in a vertical direction (Z-direction).

The first electrode 181 and the second electrode 185 may include a metal, a metal oxide, a metal nitride, a metal carbide, a metal silicide, or a combination thereof. The capacitor dielectric layer 183 may include a silicon oxide, a silicon nitride, a high-κ material, or a combination thereof.

The first insulating layer 171 may be in contact with the second source/drain region SD2 of the channel structure 110 arranged between the capacitor structure 180 and the gate electrode 140.

The gate capping layer 173 may be arranged between the gate electrode 140 and the vertical conductive electrode 160 in the first direction (X-direction) and may surround the insulating liner 175. The gate capping layer 173 may be covered by the mold structure 170. In one example, the metal growth suppression layer 120 may not be in contact with the gate capping layer 173.

The insulating liner 175 may surround the channel structure 110 disposed between the gate electrode 140 and the vertical conductive electrode 160. The insulating liner 175 may be disposed between the gate capping layer 173 and the first source/drain region SD1 of the channel structure 110.

Referring to FIGS. 4B and 5B, the semiconductor device 100′ may include a gate electrode 140′ including voids. The voids may be disposed and/or formed between the metal growth suppression layer 120 and the gate electrode 140′. In one example, the void may extend in the first direction (X-direction). In one example, when the void is included in the gate electrode 140′ disposed between the channel structures 110, the void may be closer to the second insulating layer 172 than to the first insulating layer 171 in the first direction (X-direction). In one example, the void may be disposed and/or formed between the gate electrode 140′ and the metal growth suppression layer 120 closer to the vertical conductive electrode 160 than to the capacitor structure 180. The gate electrode 140′ is disposed and formed as the conductive material is filled adjacent to the sidewall of the first insulating layer 171, and the void may be formed due to a lack of the conductive material. In one example, the void does not contact the channel structure 110 and may be arranged and/or formed on the external surface of the gate electrode 140′. Therefore, the void does not affect the threshold voltage variation of the cell transistor (for example, the cell transistor CTR of FIG. 2). The void may be referred to as a seam, air, gap, space, or air gap.

Referring to FIG. 5C, the semiconductor device 100″ may include channel structures (110″). Each of the channel structures 110″ may have a width in the vertical direction (Z-direction) that may become smaller as it approaches the vertical conductive electrode 160 in the first direction (X-direction). In one example, the width of the channel structure 110″ in the vertical direction (Z-direction) may become smaller in a direction from the second source/drain region SD2 to the first source/drain region SD1.

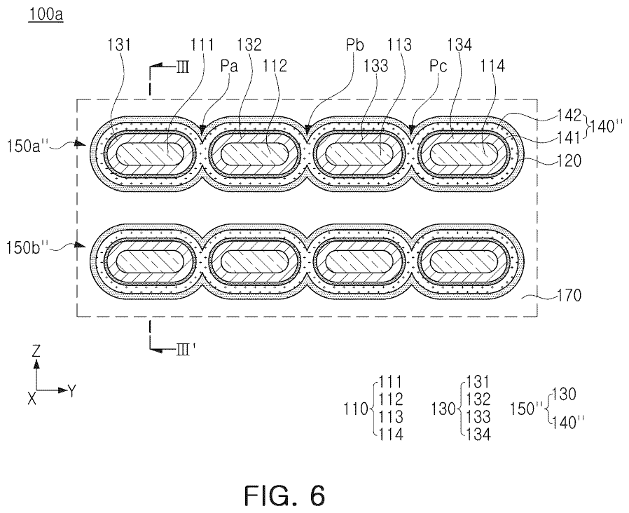

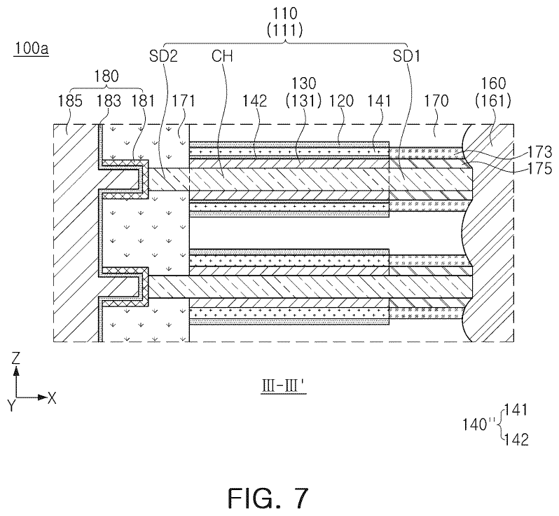

FIG. 6 is a cross-sectional view illustrating another embodiment of gate electrodes extending in one direction of the semiconductor device of FIG. 2. FIG. 7 is a cross-sectional view illustrating another embodiment of the semiconductor device along line III-III′ of FIG. 6.

Referring to FIGS. 6 and 7, the semiconductor device 100a may include gate structures 150″ including gate electrodes 140″ and gate dielectric layers 130. Each of the gate dielectric layers 130 spaced apart in the second direction (Y-direction) may surround a respective channel region CH of the channel structure 110. The gate electrode 140″ may surround the gate dielectric layers 130 spaced apart in the second direction (Y-direction). The metal growth suppression layer 120 may surround an external surface of the gate electrode 140″.

The gate structures 150″ may include a first gate structure 150a″ and a second gate structure 150b″ spaced apart in a vertical direction (Z-direction). Each of the first gate structure 150a″ and the second gate structure 150b″ may include a gate electrode 140″ and gate dielectric layers 130.

The gate electrode 140″ may include first conductive layers 141 surrounding the gate dielectric layers 130 and a second conductive layer 142 disposed on the first conductive layers 141. Each of the first conductive layers 141 may surround respective ones of each of the first to fourth gate dielectric layers 130. The first conductive layer 141 may be a seed layer for the second conductive layer 142. In one example, the second conductive layer 142 may include crystal grains formed on the surface of the first conductive layers 141 in a direction perpendicular to the surface of the first conductive layers 141. In one example, the thickness of each of the first conductive layers 141 may be smaller than the thickness of the second conductive layer 142. In one example, the first conductive layers 141 and the second conductive layer 142 may include the same metal material. The first conductive layers 141 may include first crystal grains having a first size, and the second conductive layer 142 may include second crystal grains having a second size larger than the first size. The first size of the first crystal grain may mean an average value of the maximum widths of the first crystal grains, and the second size of the second crystal grain may mean an average value of the maximum widths of the second crystal grains.

The first conductive layers 141 may be in contact with the external surface of the gate dielectric layers 131, and the second conductive layer 142 may connect the first conductive layers 141 to each other and may be in contact with the inner surface of the metal growth suppression layer 120.

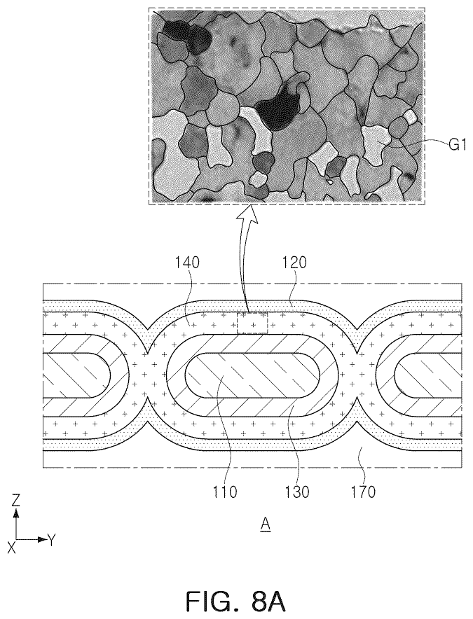

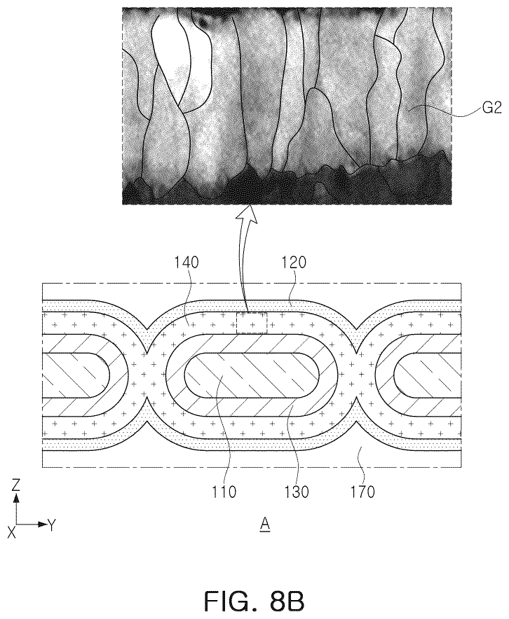

FIG. 8A is a partial enlarged cross-sectional view including a tunneling electron microscope (TEM) image according to an example embodiment of a gate electrode 140 of the gate structure of the semiconductor device of FIG. 3. FIG. 8B is a partial enlarged cross-sectional view including a TEM image according to another embodiment of a gate electrode of the gate structure of the semiconductor device of FIG. 3.

Referring to FIGS. 8A and 8B, the gate electrode 140 may include crystal grains grown from the surface of the gate dielectric layers 130 to the inner surface of the metal growth suppression layer 120 in a direction perpendicular to the surface of the gate dielectric layer 130. The gate electrode 140 may be formed without forming voids by being deposited in a single direction perpendicular to the surface of the gate dielectric layer 130.

Referring to FIG. 8A, the gate electrode 140 may have an equi-axed grain structure grown toward the metal growth suppression layer 120 on the surfaces of the gate dielectric layers 130. The equi-axed grain structure may mean a collection of crystal grains G1 of similar size in all directions that grow in a direction perpendicular to the surfaces of the gate dielectric layers 130.

Referring to FIG. 8B, the gate electrode 140 may have a columnar grain G2 structure grown toward the metal growth suppression layer 120 on the surfaces of the gate dielectric layers 130. The columnar grain structure may mean a collection of grains (G2) having a long axis extending in a direction orthogonal to the surfaces of the gate dielectric layers 130.

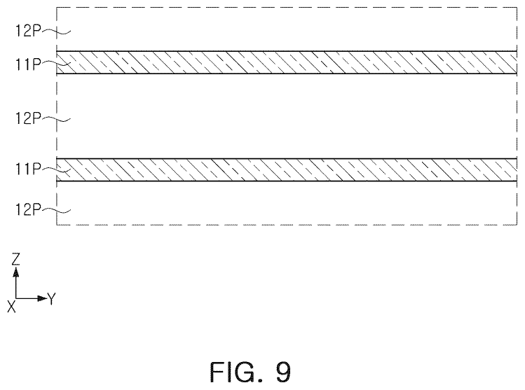

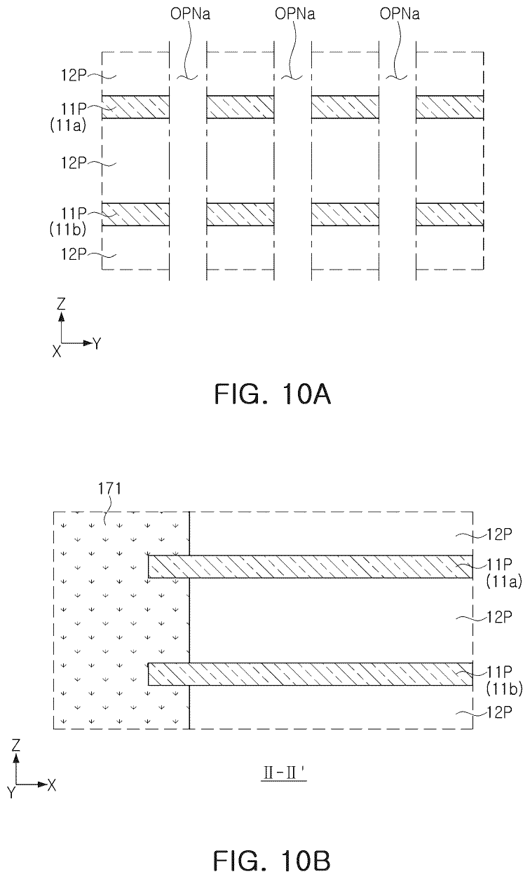

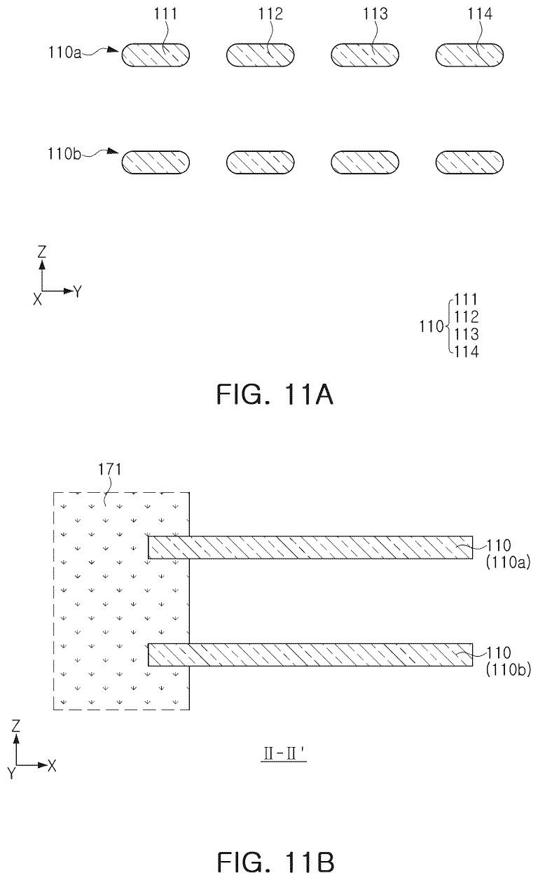

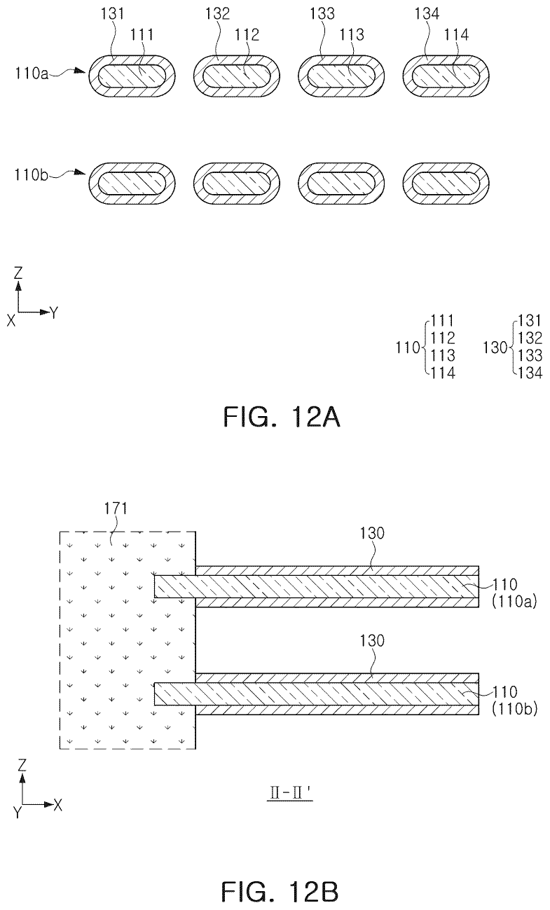

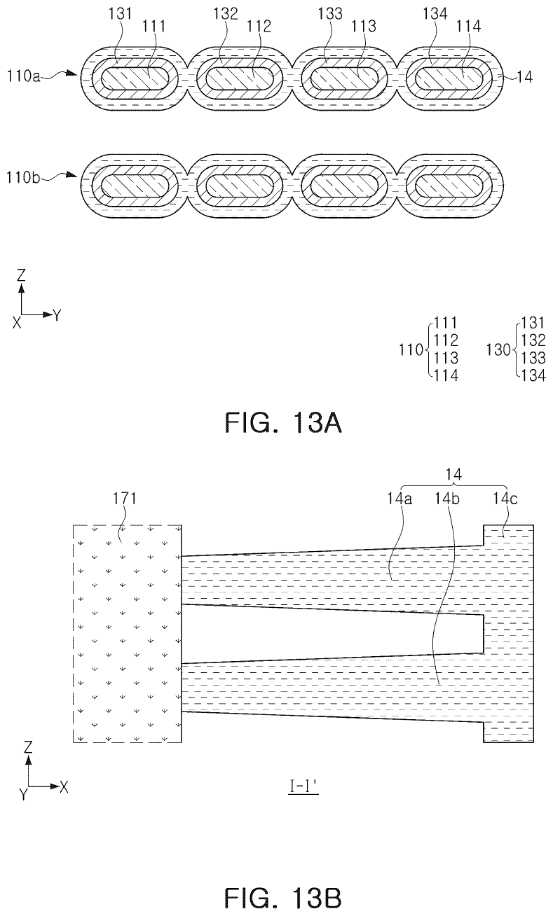

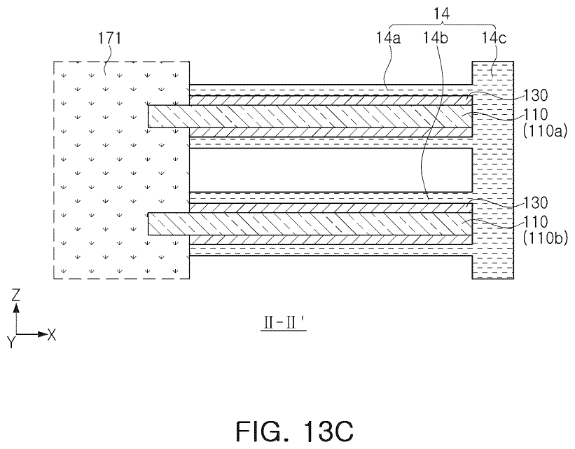

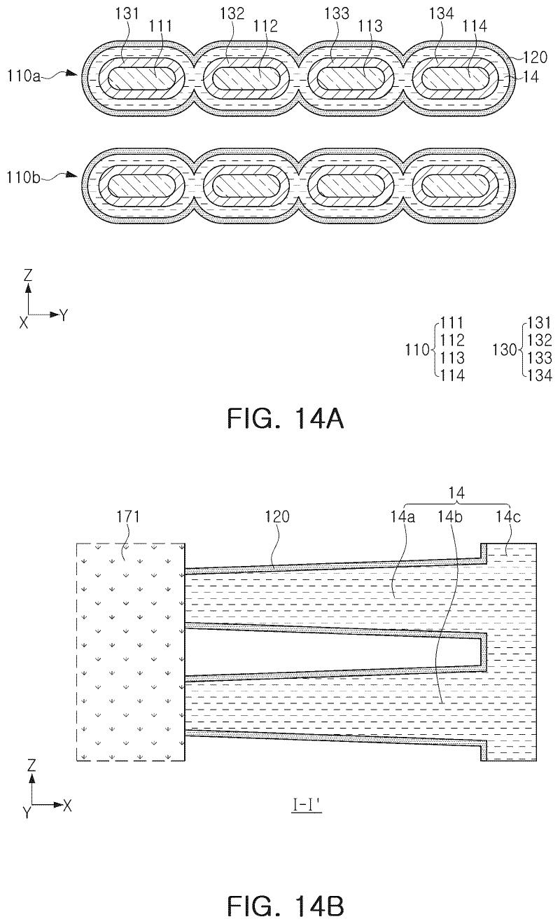

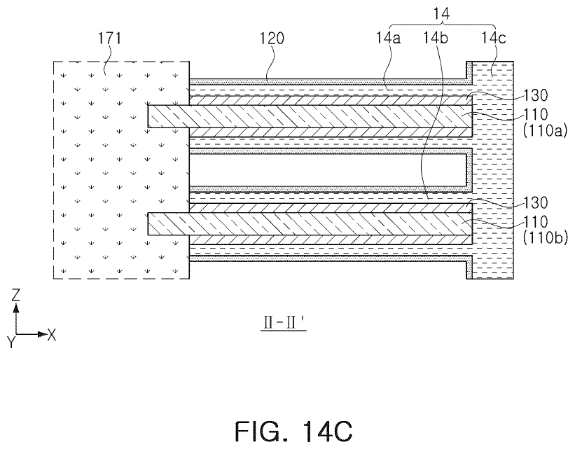

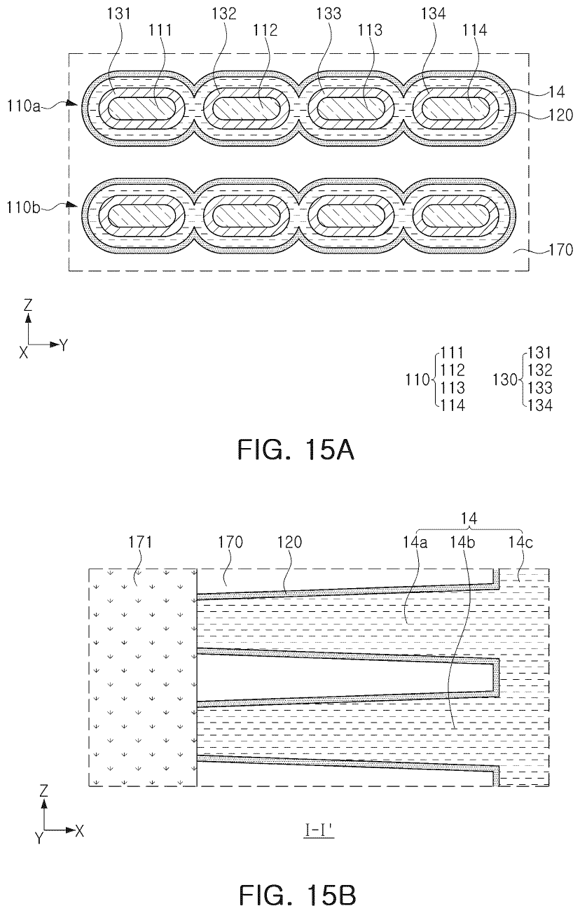

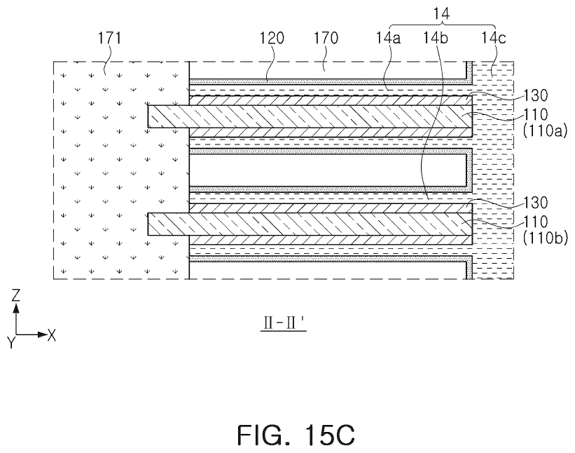

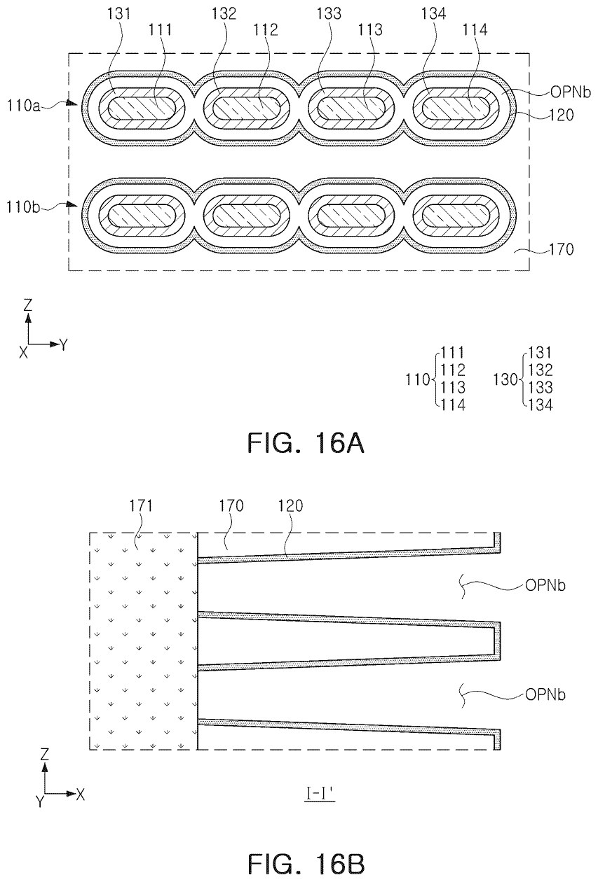

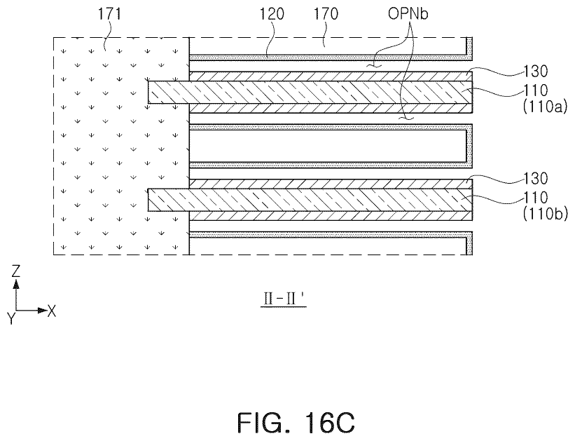

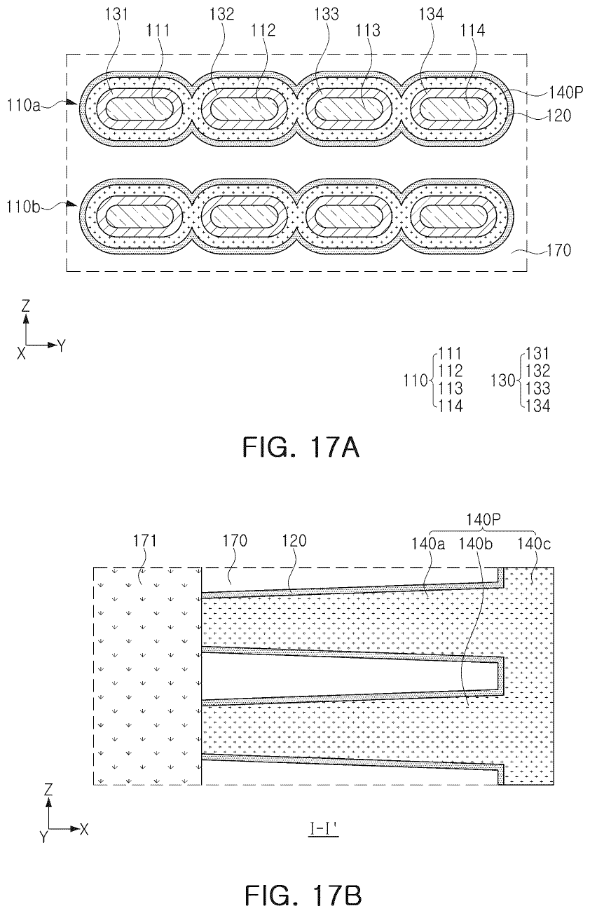

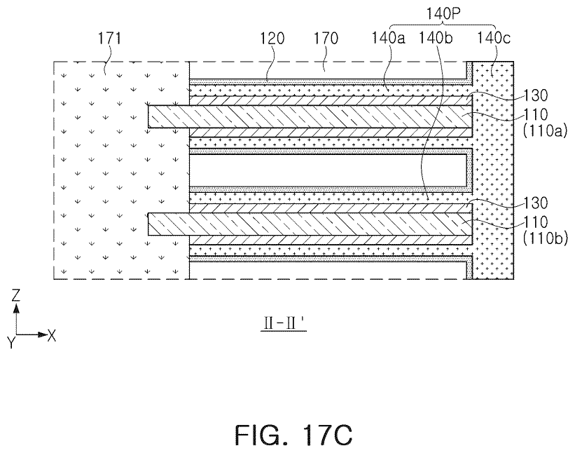

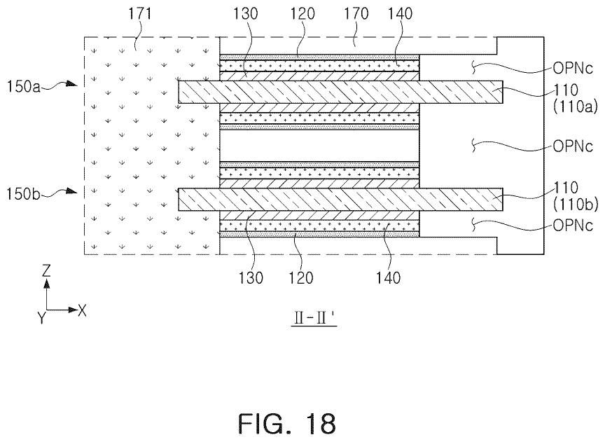

FIGS. 9 to 18 are drawings illustrating a method for manufacturing a semiconductor device according to an example embodiment. FIG. 9, FIG. 10A, FIG. 11A, FIG. 12A, FIG. 13A, FIG. 14A, FIG. 15A, FIG. 16A, and FIG. 17A illustrate cross sections corresponding to FIG. 3. FIG. 13B, FIG. 14B, FIG. 15B, FIG. 16B, and FIG. 17B illustrate cross sections corresponding to FIG. 4A, and FIG. 10B, FIG. 11B, FIG. 12B, FIG. 13C, FIG. 14C, FIG. 15C, FIG. 16C, FIG. 17C, and FIG. 18 illustrate cross sections corresponding to FIG. 5A.

Referring to FIG. 9, a stack structure may be formed in which sacrificial layers 12P and preliminary semiconductor layers 11P are alternately stacked in a vertical direction (Z-direction). The sacrificial layer 12P may include silicon germanium (SiGe), and the preliminary semiconductor layer 11P may include silicon (Si). The sacrificial layers 12P and the preliminary semiconductor layers 11P may be formed by epitaxial growth. The thickness of the preliminary semiconductor layer 11P may be smaller than the thickness of the sacrificial layer 12P.

Referring to FIG. 10A, a process of etching a stack structure in which the sacrificial layers 12P and the preliminary semiconductor layers 11P are alternately stacked in a vertical direction (Z-direction) may be performed to form first openings OPNa. The first openings OPNa may extend in the vertical direction (Z-direction) and the first direction (X-direction), e.g., in the X-Z plane. The first openings OPNa may be spaced apart from each other in the second direction (Y-direction). The preliminary semiconductor layer 11P may be referred to as the first preliminary semiconductor layer 11a when the preliminary semiconductor layer 11P is the uppermost layer of the preliminary semiconductor layers 11P, and the preliminary semiconductor layer 11P arranged below the first preliminary semiconductor layer 11a may be referred to as the second preliminary semiconductor layer 11b. In the etching process in the first direction (X-direction) and the vertical direction (Z-direction) for the first and second preliminary semiconductor layers 11a, 11b, each of the first and second preliminary semiconductor layers 11a, 11b may include a plurality of semiconductor patterns spaced apart from each other in the second direction (Y-direction).

Referring to FIG. 10B, for a stack structure in which the sacrificial layers 12P and the preliminary semiconductor layers 11P are alternately stacked in the vertical direction (Z-direction), the sacrificial layers 12P extending in the first direction (X-direction) and spaced apart from each other in the vertical direction (Z-direction) may be removed. By removing the sacrificial layers 12P, the ends of the preliminary semiconductor layers 11P are exposed, and then a first insulating layer 171 covering the ends of the exposed preliminary semiconductor layers 11P may be formed.

Referring to FIGS. 11A and 11B, the sacrificial layers 12P of FIG. 10A may be removed, and channel structures 110 may be formed by an etching process for the exposed preliminary semiconductor layers 11P. The plurality of semiconductor patterns of the first preliminary semiconductor layer 11a of FIGS. 10A and 10B may be formed as a first channel structure 110a including the first to fourth channel layers (111 to 114), and the plurality of semiconductor patterns of the second preliminary semiconductor layer 11b may be formed as a second channel structure 110b including the first to fourth channel layers (111 to 114). Each of the first to fourth channel layers (111 to 114) of the first and second channel structures 110a, 110b may have a cylindrical shape extending in the first direction (X-direction).

Referring to FIGS. 12A and 12B, gate dielectric layers 130 surrounding the exposed channel structures 110 may be formed. The gate dielectric layers 130 may be formed using, for example, chemical vapor deposition (CVD), spin coating, plasma enhanced CVD (PECVD), or high density plasma CVD (HDP-CVD). The gate dielectric layers 130 may include first to fourth gate dielectric layers (131 to 134) that conformally cover the side surfaces of the first to fourth channel layers (111 to 114). For example, each gate dielectric layer 130 may surround a corresponding channel layer when viewed along the first direction (X-direction) as shown, e.g., in FIG. 12A.

The gate dielectric layer 130 may include, for example, at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), aluminum oxide (AlO), aluminum nitride (AlN), and aluminum oxycarbonide (AlOC), and combinations thereof. The gate dielectric layer 130 is illustrated as a single film, but is not limited thereto. Unlike what is illustrated, the gate dielectric layer 130 may include a plurality of films.

Referring to FIGS. 13A to 13C, a capping layer 14 surrounding the gate dielectric layers 130 may be formed. The capping layer 14 may surround each of the gate dielectric layers 130 surrounding the first and second channel structures 110a, 110b.

Referring to FIGS. 13B and 13C, the capping layer 14 may include a first portion 14a extending in a first direction (X-direction) between the first to fourth channel layers (111 to 114) of the first channel structure 110a on the gate dielectric layers 130, a second portion 14b extending in a first direction (X-direction) between the first to fourth channel layers (111 to 114) of the second channel structure 110b on the gate dielectric layers 130, and a third portion 14c connecting the first portion 14a to the second portion 14b and extending in a vertical direction (Z-direction). The capping layer 14 formed between the first to fourth channel layers (111 to 114) does not overlap with the gate dielectric layer 130 in the vertical direction (Z-direction) and extends in the first direction (X-direction), and the height in the vertical direction (Z-direction) may decrease as it approaches the first insulating layer 171.

The capping layer 14 may be formed using, for example, chemical vapor deposition (CVD), spin coating, PECVD (Plasma Enhanced CVD), or HDP-CVD (High Density Plasma CVD).

Referring to FIGS. 14A, 14B, and 14C, a metal growth suppression layer 120 surrounding the capping layer 14 may be formed. The metal growth suppression layer 120 may cover the side surface of the first part 14a of the capping layer 14 and the side surface of the second part 14b of the capping layer 14 that extends from the side surface of the third part 14c of the capping layer 14. For example, the metal growth suppression layer 120 may surround the capping layer 14 when viewed along the first direction (X-direction) as shown, e.g., in FIG. 14A. The metal growth suppression layer 120 may be formed through the same process as the formation process of the capping layer 14. The metal growth suppression layer 120 may include a polymer compound as a layer that inhibits metal deposition. For example, the metal growth suppression layer 120 may include Octadecylphosphonic acid (ODPA).

Referring to FIGS. 15A, 15B, and 15C, a mold structure 170 (e.g., a mold or mold layer) may be formed on the metal growth suppression layer 120. The mold structure 170 may fill the space between the channel structures 110 spaced apart in the vertical direction (Z-direction), for example, the first and second channel structures 110a, 110b. The mold structure 170 may be in contact with the external surface of the metal growth suppression layer 120. The mold structure 170 may include silicon oxide.

Referring to FIGS. 16A, 16B, and 16C, the capping layer 14 of FIGS. 15A, 15B, and 15C may be removed to form second openings OPNb. The capping layer 14 may be removed by an etch-back process. The second openings OPNb may be formed between the metal growth suppression layers 120 formed between the first to fourth channel layers (111 to 114) spaced apart in the second direction (Y-direction), between the gate dielectric layers 130 surrounding the first channel structure 110a and the metal growth suppression layer 120, and between the gate dielectric layers 130 surrounding the second channel structure 110b and the metal growth suppression layer 120.

Referring to FIGS. 17A, 17B, and 17C, a preliminary gate electrode 140P filling the second openings OPNb may be formed. The preliminary gate electrode 140P may be formed by depositing a metal base material in one direction from the surface of the gate dielectric layer 130 to the inner surface of the metal growth suppression layer 120. The preliminary gate electrode 140P may fill a narrow gap space between the gate dielectric layer 130 and the metal growth suppression layer 120 without a void. However, it is not limited thereto, and in another embodiment, a void (for example, a void of FIG. 5B) may be formed between the external surface of the preliminary gate electrode 140P and the inner surface of the metal growth suppression layer 120.

Referring to FIGS. 17B and 17C, the preliminary gate electrode 140P may include a first portion 140a extending in a first direction (X-direction) between the first to fourth channel layers (111 to 114) of the first channel structure 110a on the gate dielectric layers 130, a second portion 140b extending in the first direction (X-direction) between the first to fourth channel layers (111 to 114) of the second channel structure 110b on the gate dielectric layers 130, and a third portion 140c connecting the first portion 140a to the second portion 140b and extending in a vertical direction (Z-direction). The preliminary gate electrode 140P formed between the first to fourth channel layers (111 to 114) does not overlap with the gate dielectric layer 130 in the vertical direction (Z-direction) and extends in the first direction (X-direction), and the height in the vertical direction (Z-direction) of the preliminary gate electrode 140P may become smaller as it approaches the first insulating layer 171.

Referring to FIG. 18, a third portion 140c of the preliminary gate electrode 140P of FIGS. 17B and 17C and a portion of the first and second portions 140a, 140b extending from the third portion 140c and extending in the horizontal direction (e.g., the first horizontal direction or X-direction) may be removed to form a third opening OPNc. By removing the third portion 140c of the preliminary gate electrode 140P, first and second gate structures 150a, 150b spaced apart in the vertical direction (Z-direction) may be formed. Referring to FIG. 18 together with FIG. 5A, a vertical conductive electrode 160 may be formed in the third opening OPNc. Accordingly, a semiconductor device 100 may be manufactured.

According to example embodiments, a method of manufacturing a semiconductor device includes alternately stacking sacrificial layers and preliminary semiconductor layers in a vertical direction; etching the alternately stacked sacrificial layers and preliminary semiconductor layers to form first openings extending in the vertical direction; removing the sacrificial layers to expose ends of the preliminary semiconductor layers; etching the preliminary semiconductor layers to form channels; forming gate dielectric layers each surrounding a respective channel of the channels; forming a capping layer surrounding the gate dielectric layers; forming a metal growth suppression layer surrounding the capping layer; removing the capping layer to form second openings between the metal growth suppression layer and the gate dielectric layers; and forming gate electrodes each filling a respective second opening of the second openings by depositing a metal base material such that the gate electrodes grow unidirectionally from the gate dielectric layers toward the metal growth suppression layer.

As set forth above, a semiconductor device according to example embodiments includes a metal growth suppression layer surrounding an external surface of a gate electrode, and may improve the formation of voids inside the gate electrode as the gate electrode grows unidirectionally from the surface of the gate dielectric layer in a process of forming the gate electrode. Accordingly, a semiconductor device with improved electrical characteristics may be provided.

While example embodiments have been illustrated and described above, it will be apparent to those skilled in the art that modifications and variations could be made without departing from the scope of the present inventive concept.

What is claimed is:

1. A semiconductor device comprising:
channels extending in a first horizontal direction and spaced apart from each other in a second horizontal direction intersecting the first horizontal direction;
a bit line extending in a vertical direction and contacting first ends of the channels;
a gate electrode extending in the second horizontal direction and surrounding each of the channels;
gate dielectric layers each arranged between the gate electrode and a respective channel of the channels;
a mold surrounding the gate electrode;
a metal growth suppression layer arranged between the gate electrode and the mold; and
a data storage extending in the vertical direction and contacting second ends of the channels opposite the first ends of the channels.

2. The semiconductor device of claim 1, further comprising a void disposed between the gate electrode and the metal growth suppression layer.

3. The semiconductor device of claim 2, wherein the void extends in the first horizontal direction.

4. The semiconductor device of claim 2, wherein the void is closer to the bit line than to the data storage in the first horizontal direction.

5. The semiconductor device of claim 1, wherein a thickness of the gate electrode in a direction perpendicular to outer surfaces of the gate dielectric layers is greater than a thickness of the metal growth suppression layer in the direction perpendicular to the outer surfaces of the gate dielectric layers.

6. The semiconductor device of claim 1, wherein the gate dielectric layers contact an inner surface of the gate electrode, and
wherein the metal growth suppression layer contacts an external surface of the gate electrode.

7. The semiconductor device of claim 1, wherein the gate electrode includes first conductive layers each surrounding a respective gate dielectric layer of the gate dielectric layers and a second conductive layer on the first conductive layers.

8. The semiconductor device of claim 7, wherein each of the first conductive layers is in contact with the respective gate dielectric layer of the gate dielectric layers, and
wherein the first conductive layers do not contact the metal growth suppression layer.

9. The semiconductor device of claim 7, wherein the second conductive layer includes grains that grow in a direction perpendicular to surfaces of the first conductive layers.

10. The semiconductor device of claim 1, wherein the gate electrode has a columnar grain structure having a long axis in a direction perpendicular to surfaces of the gate dielectric layers.

11. The semiconductor device of claim 1, wherein the gate electrode has an equi-axed grain structure that grows from surfaces of the gate dielectric layers toward the metal growth suppression layer.

12. The semiconductor device of claim 1, wherein the metal growth suppression layer includes octadecylphosphonic acid (ODPA).

13. The semiconductor device of claim 1, wherein a portion of the gate electrode arranged between adjacent channels of the channels has a cross-sectional area, when viewed along the second horizontal direction, that decreases as the portion of the gate electrode approaches the data storage in the first horizontal direction.

14. A semiconductor device comprising:
channels arranged three-dimensionally in a vertical direction and a first horizontal direction;
bit lines each extending in the vertical direction and contacting a first end of a respective channel of the channels;
gate electrodes each surrounding a respective channel of the channels and extending in the first horizontal direction and spaced apart from each other in the vertical direction;
gate dielectric layers each arranged between a respective channel of the channels and a corresponding gate electrode of the gate electrodes;
metal growth suppression layers each arranged on an external surface of a respective gate electrode of the gate electrodes and spaced apart from each other in the vertical direction; and
a data storage extending in the vertical direction and contacting second ends of the channels opposite to the first ends of the channels,
wherein upper and lower surfaces of portions of the gate electrodes arranged between adjacent channels of the channels spaced apart in the first horizontal direction have, when viewed along the first horizontal direction, a concave profile in the vertical direction toward a center point between corresponding upper and lower surfaces, and
wherein each of the metal growth suppression layers is arranged according to a surface profile of a corresponding gate electrode of the gate electrodes.

15. The semiconductor device of claim 14, further comprising a mold in contact with external surfaces of the metal growth suppression layers.

16. The semiconductor device of claim 14, wherein each of the gate electrodes arranged between adjacent channels of the channels spaced apart in the first horizontal direction has, when viewed along the first horizontal direction, a thickness in the vertical direction that decreases as it approaches the data storage in a second horizontal direction intersecting the first horizontal direction and the vertical direction.

17. The semiconductor device of claim 14, further comprising a void arranged between a first gate electrode among the gate electrodes and a first metal growth suppression layer arranged on an external surface of the first gate electrode among the metal growth suppression layers.

18. The semiconductor device of claim 14, wherein each gate electrode of the gate electrodes includes a first conductive layer surrounding a corresponding gate dielectric layer of the gate dielectric layers and a second conductive layer arranged on the first conductive layer, and
wherein the first conductive layer of each of the gate electrodes includes a seed layer.

19. The semiconductor device of claim 18, wherein a crystal grain size of the first conductive layer of each of the gate electrodes is smaller than a crystal grain size of the second conductive layer of each of the gate electrodes.

20. A semiconductor device comprising:
a first region including a memory cell array; and
a second region vertically overlapping the first region and including a peripheral circuit,
wherein the memory cell array includes:
channels extending in a first horizontal direction and spaced apart from each other in a second horizontal direction intersecting the first horizontal direction, each of the channels including a channel region and first and second source/drain regions separated by the channel region;
bit lines each extending in a vertical direction intersecting the first horizontal direction and the second horizontal direction and contacting a first end of a respective channel of the channels;
gate dielectric layers each surrounding a respective channel region of the channel regions of the channels;
a gate electrode extending in the second horizontal direction and surrounding each of the gate dielectric layers;
a metal growth suppression layer surrounding the gate electrode; and
a data storage extending in the vertical direction and contacting second ends of the channels opposite to the first ends of the channels,
wherein the gate electrode includes a conductive material, and
wherein the metal growth suppression layer includes a polymer compound.
